(19) United States
(12) Patent Application Publication
(10) Pub. No.: US 2025/0343041 A1
(43) Pub. Date: Nov. 6, 2025

(54) SUBSTRATE-PROCESSING METHOD AND SUBSTRATE-PROCESSING SYSTEM

(71) Applicant: Tokyo Electron Limited, Minato-ku, Tokyo (JP)

(72) Inventors: Kota UMEZAWA, Nirasaki City, Yamanashi (JP); Akira SHIMIZU, Hwaseong-si, Gyeonggi-do (KR); Munehito KAGAYA, Minato-ku, Tokyo (JP); Hiroki MURAKAMI, Nirasaki City, Yamanashi (JP); Yusuke SUZUKI, Nirasaki City, Yamanashi (JP); Yuji OTSUKI, Albany, NY (US)

(21) Appl. No.: 18/723,589

(22) PCT Filed: Dec. 13, 2022
(86) PCT No.: PCT/JP2022/045823

§ 371 Date: Nov. 25, 2024

(30) Foreign Application Priority Data
Dec. 27, 2021 (JP) 2021-212907

(51) Int. Cl. H01L 21/02; C23C 16/34; C23C 16/40; C23C 16/458; C23C 16/511; C23C 16/56; H01J 37/32; H01L 23/00

(52) U.S. Cl. CPC H01L 21/0234; C23C 16/345; C23C 16/401; C23C 16/4584; C23C 16/511; C23C 16/56; H01J 37/32192; H01J 37/32715; H01L 23/562

(57) ABSTRACT

A substrate processing method includes: preparing a substrate having a front surface and a back surface with an element formed on the front surface; forming a film on an entire back surface of the substrate; and adjusting a stress of the film by locally performing a plasma processing on a portion of the film formed on the back surface of the substrate.

### TECHNICAL FIELD

The present disclosure relates to a substrate processing method and a substrate processing system.

### BACKGROUND

When forming a device such as a 3D NAND, which is made by stacking many layers, on the surface of a substrate, a large and complex stress is applied to the substrate due to a film stress, which may cause warpage of the substrate after heat treatment in a subsequent process. As a technique that can eliminate such a problem, Patent Document 1 discloses a technique of preparing a mask according to measurement results of a front surface condition of a substrate, forming a film at a desired position on a back surface of the substrate using the mask, and compensating for localized warpage of the substrate. Further, Patent Document 2 describes a film forming apparatus that can form a film at a desired position on a back surface of a substrate in order to reduce warpage of the substrate.

### Prior Art Documents

### Patent Documents

Patent Document 1: Japanese Laid-Open Publication No. 2020-77751

Patent Document 2: Japanese Laid-Open Publication No. 2020-158856

The present disclosure provides some embodiments of a technique capable of reducing warpage of a substrate caused by a stress when an element is formed on a surface of the substrate, without interfering with a subsequent photolithography process.

### SUMMARY

According to one embodiment of the present disclosure, there is provided a substrate processing method, including: preparing a substrate having a front surface and a back surface with an element formed on the front surface; forming a film on the entire back surface of the substrate; and adjusting a stress of the film by locally performing a plasma processing on a portion of the film formed on the back surface of the substrate.

According to the present disclosure, it is possible to provide a technique capable of reducing warpage of a substrate caused by a stress when an element is formed on a surface of the substrate, without interfering with a subsequent photolithography process.

### BRIEF DESCRIPTION OF DRAWINGS

FIG. 1 is a flowchart showing a substrate processing method according to one embodiment.

FIG. 2 is a schematic configuration diagram showing an example of a substrate processing system for carrying out the substrate processing method of one embodiment.

FIG. 3 is a sectional view showing an example of a film forming apparatus in the substrate processing system.

FIG. 4 is a plan view schematically showing a microwave supplier in a plasma source of the film forming apparatus shown in FIG. 3.

FIG. 5 is a sectional view showing an example of a microwave radiation mechanism of the film forming apparatus shown in FIG. 3.

FIG. 6 is a sectional view showing an example of a plasma processing apparatus in the substrate processing system.

FIG. 7 is a diagram for explaining a relative movement between the microwave radiation mechanism and the substrate in the plasma processing apparatus of FIG. 6.

FIGS. 8A to 8C are diagrams showing an example in which a modified portion is formed by plasma processing by determining a position of the microwave radiation mechanism by a movement mechanism in the plasma processing apparatus of FIG. 6 and then rotating the substrate.

FIGS. 9A and 9B are diagrams showing an example in which a modified portion is formed at a predetermined position in XY coordinates and in a predetermined shape by combining the movement of the microwave radiation mechanism by the movement mechanism and the rotation of the substrate in the plasma processing apparatus of FIG. 6.

### DETAILED DESCRIPTION

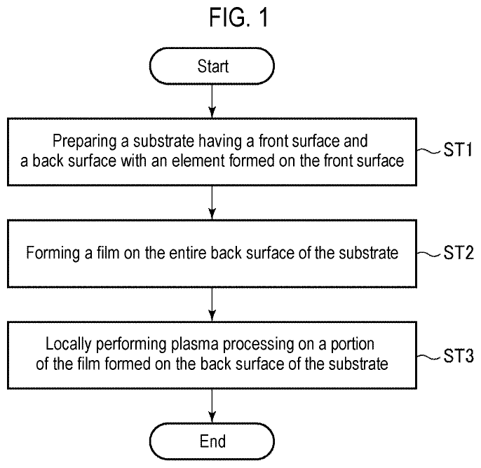

Embodiments of the present disclosure will now be described in detail with reference to the accompanying drawings. FIG. 1 is a flowchart showing a substrate processing method according to one embodiment.

In the present embodiment, first, a substrate having a front surface and a back surface with elements formed on the front surface is prepared (step ST1). Next, a film is formed on the entire back surface of the substrate (step ST2). Next, a portion of the film formed on the back surface of the substrate is locally subjected to a plasma processing (step ST3).

In step ST1, the substrate is not particularly limited. A typical example of the substrate may be a semiconductor substrate (wafer), in which case the element to be formed is a semiconductor element (semiconductor device). The element formed on the surface of the substrate is composed of a plurality of films formed by repeating a film formation process and an etching process. Since the element formed in this manner has a complicated structure, a stress of the film is applied to the substrate, and the substrate may warp due to heat treatment in a subsequent process. In particular, when a device such as a 3D NAND, which is formed by stacking 100 or more layers of films, is formed on a substrate, the stress becomes large and complicated, and the warpage of the substrate becomes large and complicated.

In step ST2, the stress is adjusted by forming a film over the entire back surface of the substrate. In this case, the “entire back surface” does not have to be completely the entire surface, and may refer to, for example, a case where a film is not formed in an extremely narrow region at the edge of the substrate. In an as-deposited state where a film is formed on the entire back surface of the substrate, the film stress may be a tensile stress.

Although the film formed on the back surface of the substrate is not particularly limited, for example, a silicon nitride (SiN) film may be used. Although the method of forming the film is not particularly limited, plasma chemical vapor deposition (CVD), particularly microwave plasma CVD, may be suitably used. When forming a SiN film as the film on the back surface, the film stress in the as-deposited state is a tensile stress. As the film formed on the back surface, in addition to the SiN film, a SiO film or a Si film may also be used.

For example, if the film formed on the back surface of the substrate is a SiN film, plasma CVD may be suitably used. When forming the SiN film by the plasma CVD, a Si-containing gas and a nitrogen-containing gas may be used and, for example, a microwave plasma source may be used as the plasma source. The thickness of the film formed on the back surface of the substrate may be, for example, in the range of 10 to 500 nm.

A local plasma processing in step ST3 has a function of modifying the film formed on the back surface of the substrate and adjusting the stress of the film. For example, if the film stress when the film is formed on the entire back surface is a tensile stress, the film stress may be changed toward a compressive direction by a plasma processing. The amount of change in the film stress due to the plasma processing at this time may be adjusted by at least one of the type of the processing gas used for the plasma processing or the electric power supplied for plasma generation. In addition, the amount of change in the film stress may also be adjusted by the gas flow rate or the like.

In step ST3, the position where the local plasma processing is performed on the back surface of the substrate is determined depending on the film stress on the front surface side of the substrate. An element with a complex structure is formed on the front surface of the substrate by repeating a film formation process and an etching process, and a complex stress distribution exists on the front surface side of the substrate. For this reason, the stress (stress distribution) on the front surface side of the substrate is measured in advance, and the position for local plasma processing is determined so that the film stress distribution on the back surface side of the substrate compensates for the stress distribution on the front surface side. As the processing gas for performing plasma processing, a gas capable of modifying the film formed on the back surface of the substrate and adjusting the stress thereof, for example, H₂, Ar, NH₃, N₂, O₂, NO, or N₂O, may be used. These gases may be used alone or in combination.

For example, when the film formed on the back surface of the substrate is a SiN film, the film stress is a tensile stress as a whole. By modifying the SiN film with, for example, H₂/Ar plasma or Ar plasma, the stress in the modified portion can be changed toward a compressive direction to adjust the stress on the back surface side of the substrate. Furthermore, by performing a modification using NH₃/Ar plasma, the stress in the modified portion can be further changed toward a tensile direction to adjust the stress on the back surface side of the substrate. When the film formed on the back surface side of the substrate is a SiO film, the stress on the back surface side of the substrate can be adjusted by modifying the SiO film with plasma of H₂, Ar, O₂, NO or N₂O, or a combination thereof. When the film formed on the back surface of the substrate is a Si film, the stress on the back surface side of the substrate can be adjusted by performing a modification with plasma of H₂, Ar, NH₃, N₂, O₂, NO or N₂O, or a combination thereof.

Such local plasma processing can be performed using an apparatus that includes a plasma source capable of generating a local plasma and a movement mechanism for causing a relative movement between the substrate and the plasma source. By causing the relative movement between the substrate and the plasma source using the movement mechanism, it is possible to adjust the position where the plasma processing of the film on the back surface of the substrate is performed. As the plasma source, for example, a plasma source that locally irradiates microwaves to generate a microwave plasma may be used. Examples of the movement mechanism include a mechanism that rotates the plasma source in a plane parallel to the substrate and rotates the substrate to cause the relative movement.

As mentioned above, in the past, as the technique of coping with the warpage of the substrate caused by the increase in the film stress due to the increase in the number of layers of an element formed on the front surface of the substrate, a technique has been used in which depending on the stress on the front surface of the substrate, a film is locally formed at a desired position on the back surface side of the substrate to compensate for local warpage of the substrate (see Patent Documents 1 and 2 cited above).

However, a substrate having a film locally formed on its back surface may possibly be rejected in a subsequent photolithography process due to accuracy issues and other reasons.

Therefore, in the present embodiment, a film is formed on the entire back surface of the substrate, and a portion of the film formed on the back surface is locally plasma-processed. As a result, since the film is formed over the entire back surface of the substrate, the warpage of the substrate due to the film stress can be reduced without interfering with a subsequent photolithography process.

### Substrate Processing System

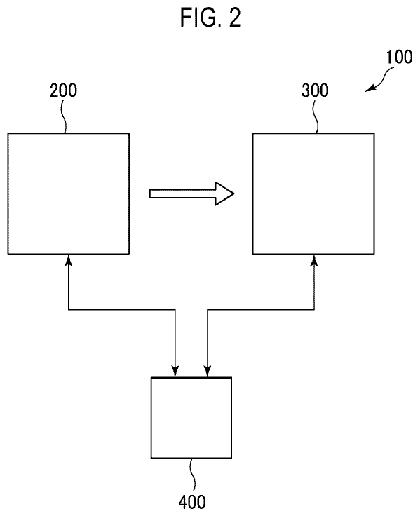

Next, a substrate processing system for carrying out the substrate processing method of one embodiment will be described. FIG. 2 is a schematic configuration diagram showing an example of a substrate processing system for carrying out the substrate processing method of one embodiment.

A substrate processing system 100 includes a film forming apparatus 200 configured to form a film on the entire back surface of a substrate, a plasma processing apparatus 300 configured to locally perform plasma processing on a portion of the film formed on the back surface of the substrate, and a controller 400.

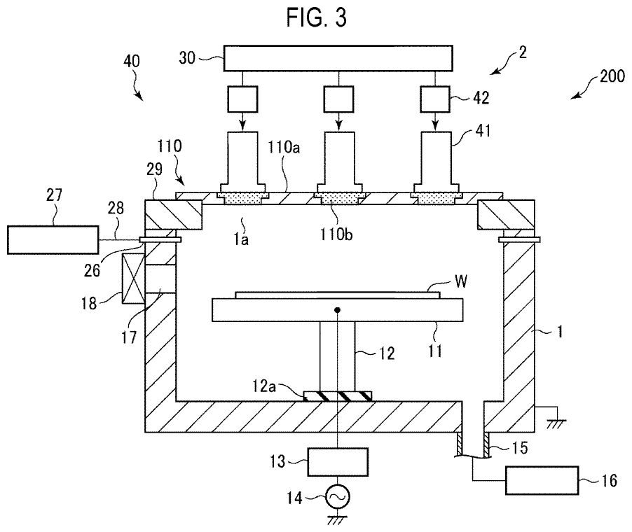

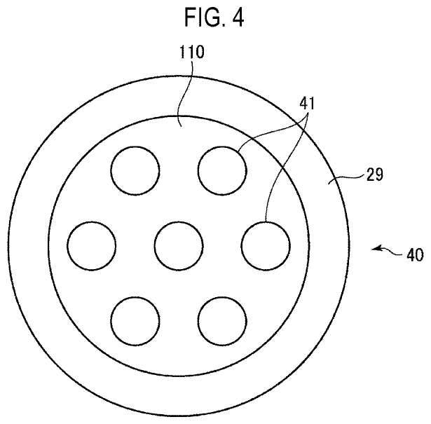

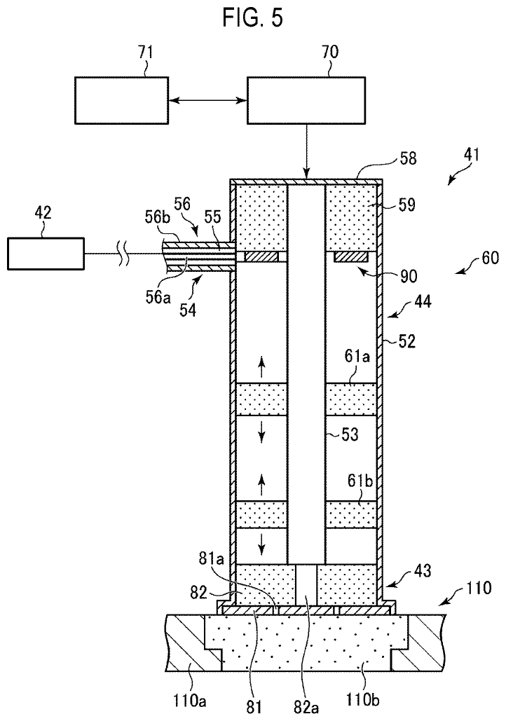

First, the film forming apparatus 200 will be described. FIG. 3 is a sectional view showing an example of the film forming apparatus 200. FIG. 4 is a plan view schematically showing a microwave supplier in a plasma source of the film forming apparatus 200 shown in FIG. 3. FIG. 5 is a sectional view showing a microwave radiation mechanism of the film forming apparatus 200 shown in FIG. 3.

The film forming apparatus 200 is configured as a plasma CVD apparatus that forms a film using a microwave plasma. For example, a SiN film is formed as the film.

The film forming apparatus 200 includes an airtight substantially-cylindrical grounded chamber 1 made of a metal material such as aluminum or stainless steel, and a plasma source 2 for radiating microwaves into the chamber 1 to form a microwave plasma. An opening la is formed in an upper portion of the chamber 1, and the plasma source 2 is provided so as to face the inside of the chamber 1 through the opening la.

A stage 11, which is a support member that horizontally supports a substrate W, is installed in the chamber 1 in a state in which the stage 11 is supported by a cylindrical support member 12 installed upright at the center of a bottom portion of the chamber 1 with an insulating member 12a interposed therebetween. A substrate W is supported on the stage 11 with its back face facing upward. Examples of the material constituting the stage 11 and the support member 12 include aluminum whose surface has been anodized.

Although not shown, the stage 11 also includes a heater for heating the substrate W, a gas flow path for supplying a heat transfer gas to the back surface of the substrate W, and lift pins that move up and down to transfer the substrate W. The stage 11 may be provided with an electrostatic chuck for electrostatically attracting the substrate W. Further, a radio-frequency bias power source 14 is electrically connected to the stage 11 via a matching box 13. By supplying the radio frequency power to the stage 11 from the radio-frequency bias power source 14, ions in the plasma are drawn toward the wafer W. The radio-frequency bias power source 14 is not essential.

An exhaust pipe 15 is connected to the bottom portion of the chamber 1, and an exhaust device 16 including a vacuum pump is connected to the exhaust pipe 15. By operating the exhaust device 16, the gas inside the chamber 1 is discharged, making it possible to quickly reduce the pressure inside the chamber 1 to a predetermined degree of vacuum. Further, the exhaust device 16 has a pressure control valve (not shown), and controls the pressure inside the chamber 1 to a predetermined pressure. A side wall of the chamber 1 is provided with a loading/unloading port 17 for loading and unloading the substrate W, and a gate valve 18 for opening and closing the loading/unloading port 17.

In the upper portion of the chamber 1, a ring-shaped gas introduction member 26 is installed along the chamber wall. The gas introduction member 26 has a large number of gas discharge holes on its inner periphery. A gas supply source 27 that supplies processing gases is connected to the gas introduction member 26 via a pipe 28. When forming a SiN film as a film, a Si-containing gas and a nitrogen-containing gas may be used as the processing gases. In addition to these gases, a rare gas such as an Ar gas or the like may be supplied. As the Si-containing gas, for example, a silane-based compound gas such as a monosilane (SiH₄) gas, a disilane (Si₂H₆) gas, a trimethylsilane (SiH(CH₃)₃) gas or the like may be used. Further, as the nitrogen-containing gas, for example, an ammonia (NH₃) gas, a nitrogen (N₂) gas or the like may be used. The processing gases may be introduced from other locations such as the ceiling wall of the chamber 1 and the like.

The gas introduced into the chamber 1 from the gas introduction member 26 is excited into plasma by the microwaves introduced into the chamber 1 from the plasma source 2, and a film is formed on the entire back surface of the substrate W by plasma CVD.

The plasma source 2 is used for radiating microwaves into the chamber 1 to form plasma, and includes a circular plate member 110 supported by a support ring 29 installed in the upper portion of the chamber 1. The gap between the support ring 29 and the plate member 110 is airtightly sealed. The plate member 110 also functions as the ceiling wall of the chamber 1.

The plasma source 2 is used for generating microwaves and radiating the generated microwaves into the chamber 1 to generate plasma, and includes a microwave output part 30 and a microwave supplier 40.

The microwave output part 30 includes a microwave power source, a microwave oscillator that oscillates microwaves, an amplifier that amplifies the oscillated microwaves, and a distributor that distributes the amplified microwaves to a plurality of parts. Then, the microwaves are distributed and outputted to a plurality of parts.

The microwave supplier 40 includes a plurality of amplifier 42 that mainly amplify the microwaves distributed by the distributor of the microwave output part 30, and a plurality of microwave radiation mechanisms 41 respectively connected to the plurality of amplifier 42.

For example, as shown in FIG. 4, the microwave radiation mechanisms 41 are arranged on the plate member 110, six along the circumference and one at the center, for a total of seven. The number of microwave radiation mechanisms 41 is not limited to seven.

The plate member 110 functions as a vacuum seal and a microwave transmission plate, and includes a metal frame 110a and microwave transmission windows 110b made of a dielectric material such as quartz or the like fitted into the frame 110a. The microwave transmission windows 110b are installed so as to correspond to the portions where the microwave radiation mechanisms 41 are arranged.

As shown in FIG. 5, the microwave radiation mechanism 41 includes a coaxial waveguide 44 that transmits microwaves, and an antenna 43 that radiates the microwaves transmitted through the waveguide 44 into the chamber 1. The microwaves radiated into the chamber 1 from the microwave radiation mechanism 41 are combined in a space inside the chamber 1, so that the microwave plasma is formed inside the chamber 1.

The waveguide 44 includes a cylindrical outer conductor 52 and a rod-shaped inner conductor 53 installed at the center of the outer conductor 52, which are coaxially arranged. The antenna 43 is installed at the tip of the waveguide 44. In the waveguide 44, the inner conductor 53 is on the power feeding side, and the outer conductor 52 is on the ground side. The upper ends of the outer conductor 52 and the inner conductor 53 serve as a reflection plate 58.

A power feeding mechanism 54 that feeds microwaves (electromagnetic waves) is installed on the base end side of the waveguide 44. The power feeding mechanism 54 has a microwave power introduction port 55 installed on the side surface of the waveguide 44 (outer conductor 52) and configured to introduce microwave power. A coaxial line 56 consisting of the inner conductor 56a and the outer conductor 56b is connected to the microwave power introduction port 55 as a power feeding line for feeding the microwaves amplified in the amplifier 42. A power feeding antenna 90 that extends horizontally toward the inside of the outer conductor 52 is connected to the tip of the inner conductor 56a of the coaxial line 56.

As the power feeding antenna 90 radiates microwaves, microwave power is fed to the space between the outer conductor 52 and the inner conductor 53. Then, the microwave power fed to the power feeding mechanism 54 propagates toward the antenna 43.

A tuner 60 is installed in the waveguide 44. The tuner 60 includes two slugs 61a and 61b installed between the outer conductor 52 and the inner conductor 53, and an actuator 70 installed outside (on the upper side) of the reflection plate 58 to drive the slugs. By independently driving the two slugs 61a and 61b up and down with the actuator 70, the impedance of the load (plasma) in the chamber 1 is matched to the characteristic impedance of the microwave power source in the microwave output part 30.

The positions of the slugs 61a and 61b are controlled by a slug controller 71. For example, the slug controller 71 sends a control signal to a motor constituting the actuator 70 based on the impedance value of an input terminal detected by an impedance detector (not shown) and the position information of the slugs 61a and 61b detected by an encoder or the like. As a result, the positions of the slugs 61a and 61b are controlled and the impedance is adjusted. The slug controller 71 performs impedance matching so that the termination becomes, for example, 50Ω.

The antenna 43 includes a planar slot antenna 81 having a planar shape, and a wave retardation material 82 installed on the back surface (upper surface) of the planar slot antenna 81. A cylindrical member 82a made of a conductor connected to the inner conductor 53 passes through the center of the wave retardation material 82, and the cylindrical member 82a is connected to the planar slot antenna 81. The wave retardation material 82 and the planar slot antenna 81 have a disk shape with a larger diameter than the outer conductor 52. The lower end of the outer conductor 52 extends to the planar slot antenna 81, and the outer conductor 52 covers the periphery of the wave retardation material 82.

The planar slot antenna 81 has slots 81a that radiate microwaves. The number, arrangement, and shape of the slots 81a are appropriately set so that the microwaves are efficiently radiated. A dielectric material may be inserted into the slots 81a.

The wave retardation material 82 has a dielectric constant greater than that of vacuum, and is made of, for example, quartz, ceramics, fluorine-based resin such as polytetrafluoroethylene, or polyimide resin. The wave retardation material 82 has a function of making the wavelength of the microwaves shorter than that in vacuum and making the antenna smaller. The wave retardation material 82 can adjust the phase of the microwaves depending on its thickness, and the thickness thereof is adjusted so that the planar slot antenna 81 becomes the “antinode” of a standing wave. As a result, the reflection can be minimized, and the radiation energy of the planar slot antenna 81 can be maximized.

The above-mentioned microwave transmission window 110b is arranged on the further tip side of the planar slot antenna 81. Then, the microwaves amplified by the amplifier 42 pass between the peripheral walls of the inner conductor 53 and the outer conductor 52, transmit through the microwave transmission window 110b from the planar slot antenna 81, and is radiated into the space inside the chamber 1. The microwave transmission window 110b may be made of the same dielectric material as the wave retardation material 82.

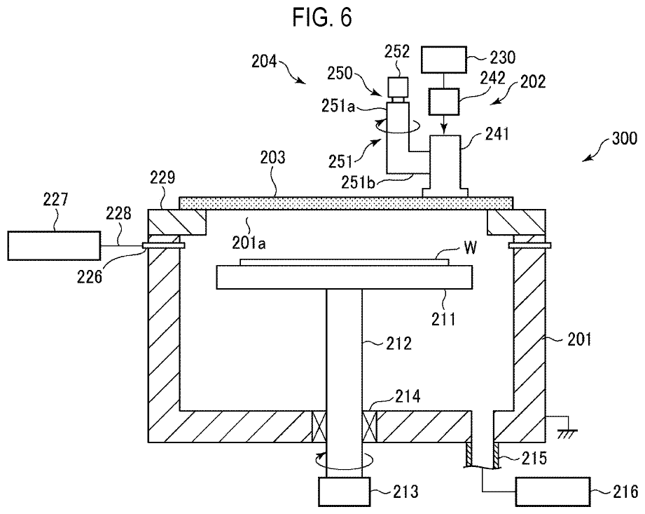

Next, the plasma processing apparatus 300 will be described. FIG. 6 is a sectional view showing an example of the plasma processing apparatus 300.

The plasma processing apparatus 300 includes an airtight substantially-cylindrical grounded chamber 201 made of a metal material such as aluminum or stainless steel, a plasma source 202 provided above the chamber 201, and a relative movement mechanism 204 that causes a relative movement between the plasma source 202 and the substrate W.

A support ring 229 is installed in an upper portion of the chamber 201, an opening 201a is formed in the support ring 229, and a top plate 203 made of a dielectric material is provided above the support ring 229 so as to close the opening 201a. The gap between the support ring 229 and the top plate 203 is airtightly sealed.

A stage 211 serving as a support member for horizontally supporting the substrate W is provided in the chamber 201 in a state in which the stage 211 is supported by a cylindrical support member 212 installed upright at the center of a bottom portion of the chamber 201. The substrate W is supported on the stage 211 with its back surface facing upward. Examples of the material constituting the stage 211 and the support member 212 include aluminum whose surface has been anodized. The support member 212 extends to below the chamber 201 through a through-hole formed in the bottom wall of the chamber 201, and the lower end thereof is connected to a rotation mechanism 213. The rotation mechanism 213 is configured to rotate the stage 211 via the support member 212, and the substrate W on the stage 211 is rotated together with the stage 211. Although not shown, the stage 211 can be moved up and down by an elevating mechanism. Further, although not shown, the stage 211 includes a temperature control mechanism for controlling the temperature of the substrate W, a gas flow path for supplying a heat transfer gas to the back surface of the substrate W, and lift pins for moving up and down to transfer the substrate W. The stage 211 may be provided with an electrostatic chuck for electrostatically attracting the substrate W. A sealing mechanism 214 such as a fluid seal is provided between the support member 212 and the bottom wall of the chamber 201.

An exhaust pipe 215 is connected to the bottom portion of the chamber 201, and an exhaust device 216 including a vacuum pump is connected to the exhaust pipe 215. By operating the exhaust device 216, the gas inside the chamber 201 is discharged, making it possible to quickly reduce the pressure inside the chamber 201 to a predetermined degree of vacuum. Further, the exhaust device 216 has a pressure control valve (not shown), and controls the pressure inside the chamber 1 to a predetermined pressure. A side wall of the chamber 201 is provided with a loading/unloading port for loading and unloading the substrate W, and a gate valve for opening and closing the loading/unloading port (none of which are shown).

In the upper portion of the chamber 201, a ring-shaped gas introduction member 226 is provided along the chamber wall. The gas introduction member 226 is provided with a large number of gas discharge holes on its inner periphery. A gas supply source 227 that supplies processing gases for plasma processing is connected to the gas introduction member 226 via a pipe 228. As the processing gases for plasma processing, gases that can modify the film formed on the back surface of the substrate W and adjust the stress, for example, H₂, Ar, NH₃, N₂, O₂, NO and N₂O may be used as described above. These gases may be used alone or in combination. For example, if the film formed on the substrate W is a SiN film, a modification may be performed using H₂/Ar plasma or Ar plasma as described above. However, the plasma is not limited thereto.

The plasma source 202 is used for radiating microwaves into the chamber 201 to form local plasma. The plasma source 202 includes a microwave output part 230, a microwave radiation mechanism 241, and an amplifier 242.

The microwave output part 230 includes a microwave power source, a microwave oscillator that oscillates microwaves, and an amplifier that amplifies the oscillated microwaves.

The amplifier 242 has a function of mainly amplifying the microwaves from the microwave output part 230. The microwave radiation mechanism 241 is installed to be movable on the top plate 203 made of a dielectric material, and is configured similarly to the microwave radiation mechanism 41 of the film forming apparatus 200 shown in FIG. 5 described above. That is, the microwave radiation mechanism 241 has a transmission path connected to the amplifier 242 and transmits the microwaves from the amplifier 242, a tuner for impedance matching, and an antenna that radiates the microwaves. The microwaves radiated from the microwave radiation mechanism 241 are transmitted through the top plate 203 and supplied into the chamber 201.

The relative movement mechanism 204 is composed of a movement mechanism 250 that moves the microwave radiation mechanism 241, and a rotation mechanism 213 that rotates the substrate W via the stage 211. The position where the film on the substrate W is subjected to plasma processing is adjusted by the movement mechanism 250 and the rotation mechanism 213.

The movement mechanism 250 rotates the microwave radiation mechanism 241 on the top plate 203 and includes a holding member 251 that holds the microwave radiation mechanism 241, and a rotation mechanism 252 that rotates the holding member 251. The holding member 251 includes a vertical portion 251a extending vertically downward from a position above the top plate 203 and a horizontal portion 251b extending horizontally from the lower end of the vertical portion 251a. The holding member 251 has an L-shaped cross-sectional shape. The microwave radiation mechanism 241 is held at the end of the horizontal portion 251b. The rotation mechanism 252 is located above the vertical portion 251a, and the rotation axis of the rotation mechanism 252 is located at the center of the vertical portion 251a. The vertical portion 251a is rotated by the rotation mechanism 252. As the vertical portion 251a rotates, the microwave radiation mechanism 241 held by the horizontal portion 251b rotates on the top plate 203 via the horizontal portion 251b. The microwave radiation mechanism 241 may be configured to slide on the top plate 203 when moved by the movement mechanism 250.

The relative movement mechanism 204 combines the rotation of the microwave radiation mechanism 241 on the substrate W and the rotation of the substrate W by the rotation mechanism 213 so that the microwave radiation mechanism 241 can be located at an arbitrary position on the film formed on the back surface of the substrate W.

Next, the controller 400 will be described. The controller 400 controls the operation and processing of each component of the film forming apparatus 200 and plasma processing apparatus 300 that constitute the substrate processing system 100. The controller 400 is typically a computer and includes a main controller, an input device, an output device, a display device, and a memory device. The main controller includes a CPU (central processing unit), a RAM, and a ROM. The memory device has a computer-readable storage medium such as a hard disk or the like, and is configured to record and read information necessary for control. In the controller 400, the CPU controls the substrate processing system 100 by executing programs such as processing recipes stored in the ROM or the storage medium of the memory device using the RAM as a work area. Furthermore, the controller 400 also has a function of determining the position where the film formed on the back surface of the substrate is subjected to plasma processing, depending on the film stress on the front surface side of the substrate W.

The transfer device that transfers the substrate W from the film forming apparatus 200 to the plasma processing apparatus 300 may be a transfer device that transfers the substrate W in-situ using a vacuum transfer chamber, or a transfer device that transfers the substrate W in the ambient air.

Next, the processing operation of the substrate processing system 100 configured as described above will be described. The following processing operation is performed under the control of the controller 400.

First, the substrate W is loaded into the chamber 1 of the film forming apparatus 200 and placed on the stage 11. Then, the gate valve 18 is closed. At this time, the stage 11 is heated by a heater (not shown), and the temperature of the substrate W on the stage 11 is controlled. When forming a SiN film as the film, the temperature of the substrate W is set to, for example, 500 degrees C. to 650 degrees C. After the chamber 1 is evacuated to a desired vacuum state by the exhaust device 16, processing gases are introduced into the chamber 1 from the gas supply source 27 via the pipe 28 and the gas introduction member 26, the pressure inside the chamber 1 is controlled, and a film formation is performed by plasma CVD. When forming a SiN film as the film, a Si-containing gas and a N-containing gas are used as the processing gases. If necessary, a rare gas such as an Ar gas or the like is used. Further, the pressure inside the chamber 1 may be set to, for example, 266 Pa or less.

In order to generate plasma, microwaves are outputted from the microwave output part 30 of the plasma source 2 while introducing the processing gases into the chamber 1. At this time, the microwaves distributed and outputted from the microwave output part 30 are amplified by the amplifier 42 of the microwave supplier 40 and are then supplied to the waveguide 44 of the microwave radiation mechanism 41. Then, the microwaves are radiated into the chamber 1 through the wave retardation material 82 of the antenna 43, the slots 81a of the planar slot antenna 81, and the microwave transmission window 110b. At this time, the impedance is automatically matched by moving the slugs 61a and 61b of the tuner 60, and the microwaves are supplied with substantially no power reflection. The radiated microwaves propagate on the surface of the microwave transmission window 110b. The gas introduced into the chamber 1 is excited by the electric field of the microwaves, and the plasma is formed in the plasma generation space inside the chamber 1. For example, a SiN film is formed on the entire back surface of the substrate W by plasma CVD.

Process adjustment parameters during film formation include a gas flow rate, a gas flow rate ratio, a pressure, and a microwave output radiated from each microwave radiation mechanism 41. By individually adjusting the microwave outputs of the respective microwave radiation mechanisms 41, it is possible to control the film formation distribution.

Since the electron temperature of the microwave plasma is controlled to be low, film formation can be performed without damaging the film to be formed or the elements of the substrate W. Further, since the microwave plasma is high-density plasma, the density of the obtained film can be increased, making it suitable as a film for stress adjustment.

The substrate W on which a film is formed on the entire back surface as described above is loaded into the chamber 201 of the plasma processing apparatus 300 and placed on the stage 211. After the chamber 201 is evacuated to a desired vacuum state by the exhaust device 216, processing gases are introduced into the chamber 201 from the gas supply source 227 via the pipe 228 and the gas introduction member 226, the pressure inside the chamber 201 is controlled, and a local plasma processing is performed on the back surface of the substrate W.

The local plasma processing is performed by rotating the substrate W by the rotation mechanism 213 while introducing the processing gases into the chamber 201, rotating the microwave radiation mechanism 241 by the movement mechanism 250, and radiating the microwaves to a desired position on the substrate W. That is, the microwave radiation mechanism 241, which is a part of the plasma source 202, and the substrate W are relatively moved, and the microwaves outputted from the microwave output part 230 are radiated from the microwave radiation mechanism 241 to a desired position on the substrate W, thereby generating plasma.

In this way, an arbitrary portion of the film formed on the back surface of the substrate W can be modified by plasma processing, and the stress in the modified portion can be adjusted. At this time, the degree of modification by plasma processing can be adjusted depending on the type and the flow rate of the plasma-generating gas, the plasma power, and the like. Further, the position where the local plasma processing is performed on the back surface of the substrate W is determined according to the stress on the front surface side of the substrate W.

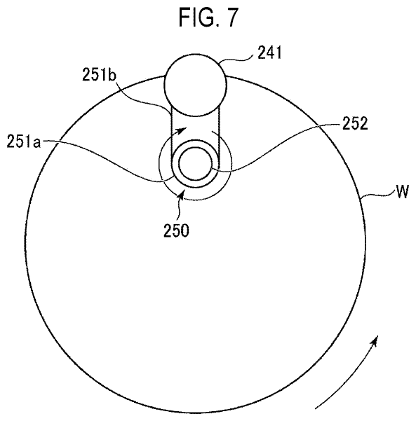

Specifically, as shown in FIG. 7, the rotation mechanism 252 of the movement mechanism 250 rotates the vertical portion 251a such that the microwave radiation mechanism 241 is rotated to determine the position of the microwave radiation mechanism 241. Further, the substrate W is rotated by the rotation mechanism 213. As a result, a plasma processing can be performed at an arbitrary position on the substrate W.

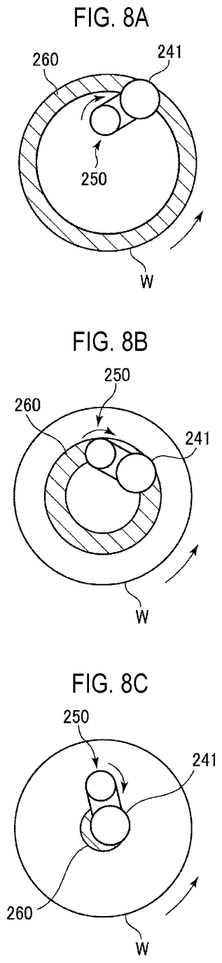

For example, in the example of FIG. 8A, the microwave radiation mechanism 241 is located at a position corresponding to the outermost periphery of the substrate W. Then, by rotating the substrate W, the outermost periphery of the film on the back surface of the substrate W is plasma-processed in a ring shape to form a modified portion 260. In the example of FIG. 8B, the microwave radiation mechanism 241 is located at a position corresponding to a middle portion of the substrate W. Then, by rotating the substrate W, the middle portion of the film on the back surface of the substrate W is plasma-processed in a ring shape to form a modified portion 260. In the example of FIG. 8C, the microwave radiation mechanism 241 is located at a position corresponding to the central portion of the substrate W. Then, by rotating the substrate W, a modified portion 260 is formed on the central portion of the film on the back surface of the substrate W.

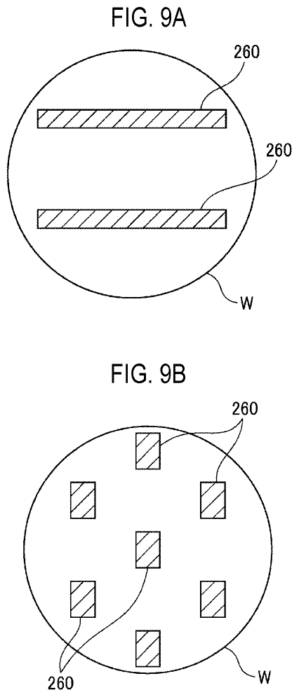

Furthermore, by combining the movement of the microwave radiation mechanism 241 using the movement mechanism 250 and the rotation of the substrate W, the modified portion 260 can be formed in an arbitrary shape at an arbitrary position on the XY coordinates. For example, linear modified portions 260 may be formed as shown in FIG. 9A, or spot-shaped modified portions 260 may be formed as shown in FIG. 9B.

The microwaves supplied into the chamber 201 from the microwave radiation mechanism 241 spread somewhat laterally. The electric field strength of the microwaves is highest at the center of the microwave radiation mechanism 241 and is low outside the microwave radiation mechanism 241. Therefore, the range of the modification by the plasma may be substantially the microwave irradiation region of the substrate W.

Since the electron temperature of the microwave plasma is controlled to be low, the plasma processing can be performed without damaging the elements of the substrate W. Furthermore, since the microwave plasma is high-density plasma, the plasma has a high modification effect.

### Experimental Example

Next, an experimental example will be described. First, a SiN film with a thickness of 25 nm was formed on the back surface of the substrate by microwave plasma CVD using the film forming apparatus shown in FIG. 3 described above. The stress of the film in the as-deposited state was tensile strength of 567 MPa.

This SiN film was plasma-processed using microwave plasma under conditions 1 and 2 below.
Condition 1
   Processing gas: H₂ gas/Ar gas
   Microwave output: 50 W
   Time: 60 sec
Condition 2
   Processing gas: Ar gas
   Microwave output: 500 W
   Time: 60 sec

The stress on the film after the plasma processing was 522 MPa under condition 1 and 244 MPa under condition 2. The stress on the film was changed toward a compressive direction in both cases. Specifically, the amount of change toward the compressive direction was 45 MPa under condition 1 and 323 MPa under condition 2. From the above results, it was confirmed that the stress of the film on the back surface of the substrate could be adjusted by the plasma processing.

### Other Applications

Although the embodiment has been described above, the embodiment disclosed herein should be considered to be exemplary in all respects and not limitative. The embodiment described above may be omitted, replaced, and modified in various forms without departing from the scope and spirit of the appended claims.

For example, in the above-described embodiment, there has been shown the example in which the microwave plasma CVD is used to form the film on the entire back surface of the substrate. However, the present disclosure is not limited thereto. Any film forming method that can adjust the stress of elements on the front surface side of the substrate may be adopted. For example, other methods such as plasma CVD, thermal CVD, atomic layer deposition (ALD), physical vapor deposition (PVD), and the like may be used. Further, in the above-described embodiment, the SiN film was used as the film formed on the entire back surface of the substrate. However, any film that can adjust the stress of the elements on the front surface side of the substrate may be used. In addition to the SiN film, for example, a SiO film or a Si film may also be used.

In addition, in the above-described embodiment, there has been shown the example in which the microwave plasma is used for the plasma processing of the film on the back surface of the substrate. However, any plasma processing capable of adjusting the stress of the film on the back surface of the substrate may be used, and other plasma such as such as capacitively coupled plasma or inductively coupled plasma may also be used. Furthermore, in the above-described embodiment, there has been shown the example in which the local plasma is formed using the microwave radiation mechanism. However, the present disclosure is not limited thereto. A remote plasma unit for generating plasma at a location other than the chamber may be used so as to radiate a gas that has been turned into plasma by the remote plasma unit. Furthermore, in the above-described embodiment, there has been described the example in which the movement mechanism rotates the microwave radiation mechanism constituting the plasma source and rotates the substrate to cause relative movement between the plasma source and the substrate, thereby adjusting the position where local plasma processing is performed. However, the present disclosure is not limited thereto. For example, the position where local plasma processing is performed on the substrate may be adjusted using an XY table that can arbitrarily move the substrate on the XY coordinates with respect to a fixedly-provided plasma source.

### EXPLANATION OF REFERENCE NUMERALS

100: substrate processing system, 200: film forming apparatus, 201: chamber, 202: plasma source, 211: stage, 213: rotation mechanism, 227: gas supply source, 241: microwave radiation mechanism, 250: movement mechanism, 260: modified portion, 300: plasma processing apparatus, 400: controller, W: substrate

1. A substrate processing method, comprising:
preparing a substrate having a front surface and a back surface with an element formed on the front surface;
forming a film on an entire back surface of the substrate; and
adjusting a stress of the film by locally performing a plasma processing on a portion of the film formed on the back surface of the substrate.

2. The substrate processing method of claim 1, wherein the element is formed of multiple films stacked one above another.

3. The substrate processing method of claim 1, wherein a position where the plasma processing is performed on the film is determined depending on the stress of the film on the front surface of the substrate.

4. The substrate processing method of claim 1, wherein the plasma processing is performed using an apparatus including a plasma source capable of generating a local plasma and a relative movement mechanism configured to cause a relative movement between the substrate and the plasma source, and
wherein a position where the plasma processing is performed on the film on the substrate is adjusted by the relative movement mechanism.

5. The substrate processing method of claim 1, wherein the film formed in the forming the film on the entire back surface of the substrate has a tensile stress.

6. The substrate processing method of claim 5, wherein the film is a SiN film.

7. The substrate processing method of claim 5, wherein the film is a SiO film.

8. The substrate processing method of claim 5, wherein the forming the film is performed by a microwave plasma CVD.

9. The substrate processing method of claim 5, wherein the stress of the film is changed toward a compressive direction by the plasma processing.

10. The substrate processing method of claim 9, wherein the amount of change in the stress due to the plasma processing is adjusted by at least one of a type of a processing gas used for the plasma processing or a power supplied for a plasma generation.

11. A substrate processing system, comprising:
a film forming apparatus configured to form a film on an entire back surface of a substrate having a front surface and a back surface with an element formed on the front surface; and
a plasma processing apparatus configured to locally perform a plasma processing on a portion of the film formed on the back surface of the substrate to adjust a stress of the film.

12. The substrate processing system of claim 11, further comprising:
a controller configured to control the film forming apparatus and the plasma processing apparatus,
wherein the controller determines a position where the plasma processing is performed on the film, depending on the stress of the film on the front surface of the substrate.

13. The substrate processing system of claim 11, wherein the plasma processing apparatus includes a chamber configured to perform the plasma processing on the substrate, a plasma source capable of generating a local plasma, and a relative movement mechanism configured to cause a relative movement between the substrate and the plasma source, and wherein a position where the plasma processing is performed on the film is adjusted by the relative movement mechanism.

14. The substrate processing system of claim 13, wherein the plasma source comprises:
a microwave output part; and
a microwave radiation mechanism installed to be movable on a top plate of the chamber made of a dielectric material, and configured to radiate microwaves outputted from the microwave output part into the chamber via the top plate,
wherein the plasma source is configured to generate microwave plasma in the chamber, and
wherein the relative movement mechanism comprises:
a movement mechanism configured to rotate the microwave radiation mechanism along the top plate; and
a rotation mechanism configured to rotate the substrate.

15. The substrate processing system of claim 11, wherein the film forming apparatus is configured to form a film having a tensile stress as the film formed on the entire back surface of the substrate.

16. The substrate processing system of claim 15, wherein the film forming apparatus is configured to form a SiN film as the film.

17. The substrate processing system of claim 15, wherein the film forming apparatus is configured to form a SiO film as the film.

18. The substrate processing system of claim 15, wherein the film forming apparatus is configured to form the film by a microwave plasma CVD.

19. The substrate processing system of claim 15, wherein the plasma processing apparatus is configured to change the stress of the film formed by the film forming apparatus toward a compressive direction.

20. The substrate processing system of claim 19, wherein the plasma processing apparatus is configured to adjust the amount of change in the stress due to the plasma processing by at least one of a type of a processing gas used for the plasma processing or a power supplied for a plasma generation.
